(19) United States
(12) Patent Application Publication
(10) Pub. No.: US 2015/0325618 A1
(43) Pub. Date: Nov. 12, 2015

(54) CMOS IMAGE SENSOR INCLUDING COLOR MICROLENS, AND METHOD FOR MANUFACTURING SAME

(71) Applicant: SILICONFILE TECHNOLOGIES INC., Seongnam-si Gyeonggi-do (KR)

(72) Inventors: Heui Gyun AHN, Seongnam-si, Gyeonggi-do (KR); Jun Ho WON, Seoul (KR)

(73) Assignee: SiliconFile Technologies Inc., Seongnam-si, Gyeonggi-do (KR)

(21) Appl. No.: 14/442,831

(22) PCT Filed: Apr. 24, 2013
(86) PCT No.: PCT/KR2013/003538

§ 371 Date: May 14, 2015

(30) Foreign Application Priority Data
Nov. 16, 2012 (KR) 10-2012-0129897

(51) Int. Cl. H01L 27/146

(52) U.S. Cl. CPC H01L 27/14645; H01L 27/14627; H01L 27/14621; H01L 27/1462; H01L 27/14685; H01L 27/14689

(57) ABSTRACT

The present invention relates to a CMOS image sensor including a color microlens, in which the color characteristics of a microlens are improved by replacing a microlens made of a transparent material with a material having characteristics similar to those of a color filter, and a manufacturing method thereof. In accordance with the CMOS image sensor including a color microlens and the manufacturing method thereof according to the present invention, color characteristics is improved. Since formation processes of a color filter and a microlens are performed at one time, additional processes for planarization and step difference adjustment are not necessary, so that an entire process is simplified. In the progress of light, since there is no interface between materials, reflection, refraction and the like are reduced, so that it is possible to increase light efficiency.

The present invention relates to a CMOS image sensor and a manufacturing method thereof, and particularly, to a CMOS image sensor including a color microlens, in which the color characteristics of a microlens are improved by replacing a microlens made of a transparent material with a material having characteristics similar to those of a color filter, and a manufacturing method thereof.

### BACKGROUND ART

In general, an image sensor is a semiconductor device that converts an optical image into an electrical signal, wherein a charge coupled device (CCD) is an element in which individual MOS (Metal-Oxide-Silicon) capacitors are very close to each other and a charge carrier is stored in the capacitor and is transported, and a CMOS image sensor is an element employing a switching scheme in which MOS transistors corresponding to the number of pixels are manufactured using a CMOS technology using a control circuit and a signal processing circuit as a peripheral circuit and output is sequentially detected using the MOS transistors.

In such an image sensor, color filters are arranged above a photodetection unit that receives light from an exterior and generates and accumulates photocharge, and a color filter array (CFA) may include three colors of red, green, and blue, or other colors.

Furthermore, in order to improve photosensitivity in the image sensor, a light collection technology for changing a path of incident light and collecting the light to the photodetection unit has emerged. For such light collection, the image sensor uses a method for forming a microlens on the color filter.

Meanwhile, an image sensor using a conventional front-side illumination (hereinafter, referred to as FSI) scheme has a problem that photosensitivity is reduced by interference due to an interconnection forming layer or crosstalk occurs. In order to solve such a problem, an image sensor using a back-side illumination (hereinafter, referred to as BSI) scheme has been recently used.

FIG. 1 is a diagram schematically illustrating a unit pixel of a conventional BSI CMOS image sensor.

As illustrated in FIG. 1, the unit pixel of the BSI CMOS image sensor has a structure in which a metal interconnection layer 110, a photodetection layer 120, an anti-reflective layer 130, a color filter layer 140, an over-coating layer 150, and a microlens layer 160 are sequentially stacked.

In order to optimize the light efficiency of the CMOS image sensor, an over-coating layer (OCL), which is an additional layer for planarization and step difference adjustment, is required to be provided above or below a color filter with respect to each pixel.

In such a case, an anti-reflective layer, an over-coating layer (OCL), a color filter, an over-coating layer (OCL), and a microlens (ML) are sequentially connected to one another, so that a plurality of interfaces exist. Due to reflection or refraction of light occurring in these interfaces, light collection becomes difficult and loss of light incident through an initial microlens actually occurs.

### DISCLOSURE

### Technical Problem

Accordingly, the present invention has been made in an effort to solve the problems occurring in the related art, and an object of the present invention is to provide a CMOS image sensor including a color microlens, which can improve the color characteristics of a microlens by replacing a microlens made of a transparent material with a material having characteristics similar to those of a color filter, and a manufacturing method thereof.

### Technical Solution

In order to achieve the above object, according to one aspect of the present invention, there is provided a CMOS image sensor including a color microlens including: a photodetection layer formed over a semiconductor substrate and including at least one photodiode for receiving light of at least one color; an anti-reflective layer formed over the photodetection layer; a color filter layer formed over the anti-reflective layer and including at least one color filter formed at positions respectively corresponding to the at least one photodiode; an over-coating layer formed over the color filter layer and including at least one over-coating formed at positions respectively corresponding to the at least one color filter; and a color microlens layer formed over the over-coating layer and including at least one color microlens formed at positions respectively corresponding to the at least one color filter.

In order to achieve the above object, according to another aspect of the present invention, there is provided a CMOS image sensor including a color microlens including: a photodetection layer formed over a semiconductor substrate and including at least one photodiode for receiving light of at least one color; an anti-reflective layer formed over the photodetection layer; and a color microlens layer serving as a color filter formed over the anti-reflective layer and including a color microlens serving as at least one color filter formed at positions respectively corresponding to the at least one photodiode.

In order to achieve the above object, according to another aspect of the present invention, there is provided a CMOS image sensor including a color microlens including: a photodetection layer formed over a semiconductor substrate and including at least one photodiode for receiving light of at least one color; an anti-reflective layer formed over the photodetection layer; and a color microlens layer formed over the anti-reflective layer and including at least one color microlens formed at positions respectively corresponding to the at least one photodiode.

In order to achieve the above object, according to one aspect of the present invention, there is provided a manufacturing method of a CMOS image sensor including a color microlens, including the steps of: forming a photodetection layer including at least one photodiode for receiving light of at least one color over a semiconductor substrate; forming an anti-reflective layer over the photodetection layer; forming a color filter layer including at least one color filter at positions respectively corresponding to the at least one photodiode over the anti-reflective layer; forming an over-coating layer including at least one over-coating formed at positions respectively corresponding to the at least one color filter over the color filter layer; and forming a color microlens layer including at least one color microlens formed at positions respectively corresponding to the at least one color filter over the over-coating layer.

In order to achieve the above object, according to another aspect of the present invention, there is provided a manufacturing method of a CMOS image sensor including a color microlens, including the steps of: forming a photodetection layer including at least one photodiode for receiving light of at least one color over a semiconductor substrate; forming an anti-reflective layer over the photodetection layer; and forming a color microlens layer serving as a color filter and including a color microlens serving as at least one color filter formed at positions respectively corresponding to the at least one photodiode over the anti-reflective layer.

In order to achieve the above object, according to another aspect of the present invention, there is provided a manufacturing method of a CMOS image sensor including a color microlens, including the steps of: forming a photodetection layer including at least one photodiode for receiving light of at least one color over a semiconductor substrate; forming an anti-reflective layer over the photodetection layer; and forming a color microlens layer including at least one color microlens formed at positions respectively corresponding to the at least one photodiode over the anti-reflective layer.

### Advantageous Effects

In accordance with a CMOS image sensor including a color microlens and a manufacturing method thereof, a conventional microlens made of a transparent material is changed to a color microlens, so that a CRA/Shift equation can be separately used for each color, resulting in the improvement of color characteristics.

Furthermore, since formation processes of a color filter and a microlens are performed at one time, additional processes for planarization and step difference adjustment are not necessary, so that an entire process can be simplified. In the progress of light, since there is no interface between materials, reflection, refraction and the like are reduced, so that it is possible to increase light efficiency.

### BRIEF DESCRIPTION OF THE DRAWINGS

The above objects, and other features and advantages of the present invention will become more apparent after a reading of the following detailed description taken in conjunction with the drawings, in which:

FIG. 1 is a diagram schematically illustrating a conventional BSI CMOS image sensor;

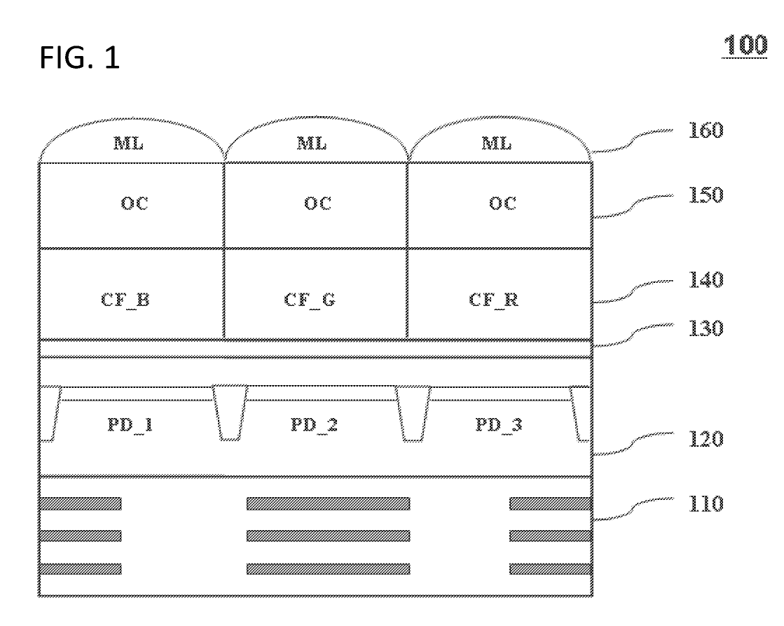

FIG. 2 is a diagram schematically illustrating a CMOS image sensor including a color microlens according to the present invention;

FIG. 3 is a diagram schematically illustrating a CMOS image sensor including a color microlens according to another embodiment of the present invention;

FIG. 4 is a diagram schematically illustrating a CMOS image sensor including a color microlens according to further another embodiment of the present invention;

FIG. 5 is a flowchart illustrating a procedure of a manufacturing method of a CMOS image sensor including a color microlens of FIG. 2;

FIG. 6 is a flowchart illustrating a procedure of a manufacturing method of a CMOS image sensor including a color microlens of FIG. 3; and

FIG. 7 is a flowchart illustrating a procedure of a manufacturing method of a CMOS image sensor including a color microlens of FIG. 4.

### BEST MODE FOR THE INVENTION

Reference will now be made in greater detail to a preferred embodiment of the invention, an example of which is illustrated in the accompanying drawings. Wherever possible, the same reference numerals will be used throughout the drawings and the description to refer to the same or like parts.

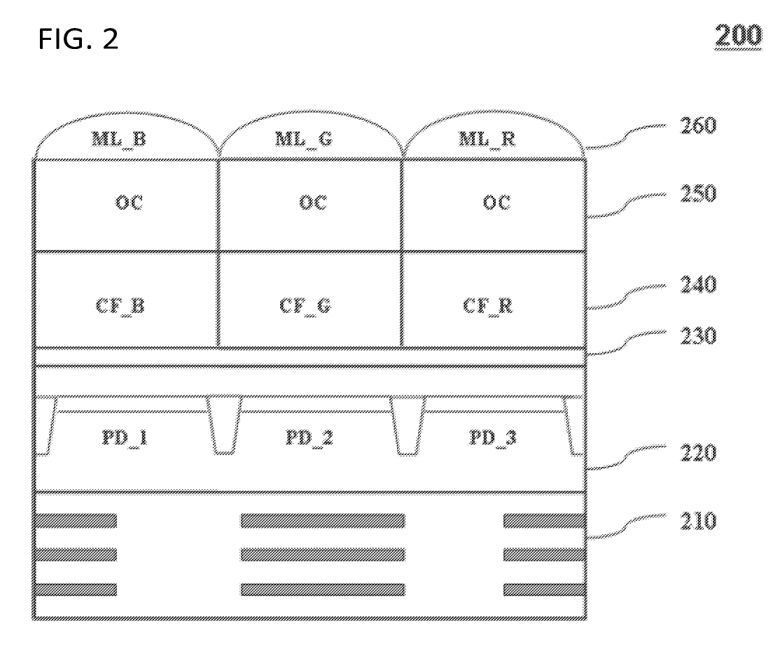

FIG. 2 is a diagram schematically illustrating a CMOS image sensor including a color microlens according to one embodiment of the present invention.

As illustrated in FIG. 2, a CMOS image sensor 200 including a color microlens according to the present invention has a structure in which a metal interconnection layer 210, a photodetection layer 220, an anti-reflective layer 230, a color filter layer 240, an over-coating layer 250, and a color microlens layer 260 are sequentially stacked.

The color microlens layer 260 is not made of a transparent material, and includes a color microlens made of a material having characteristics equal to or similar to those of the color filter layer 240. That is, the present invention is characterized in that a conventional general microlens is changed to a color microlens to improve color characteristics.

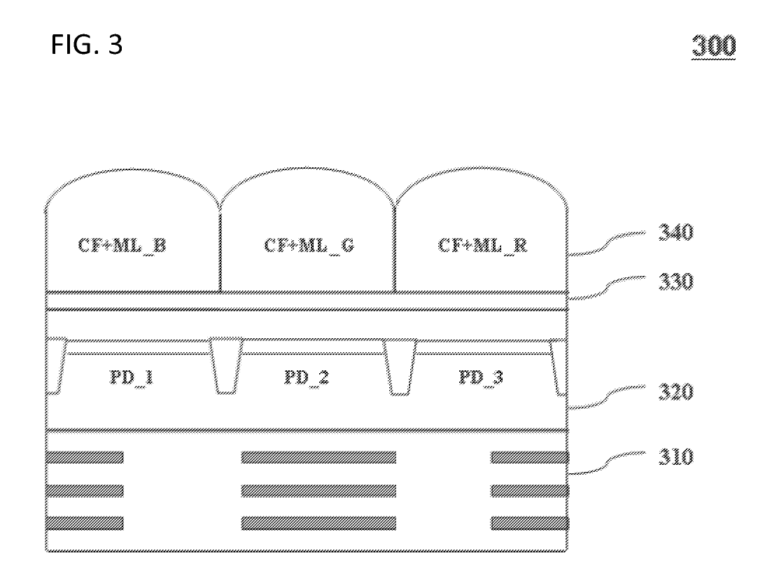

FIG. 3 is a diagram schematically illustrating a CMOS image sensor including a color microlens according to another embodiment of the present invention.

As illustrated in FIG. 3, a CMOS image sensor 300 including a color microlens according to the present invention has a structure in which a metal interconnection layer 310, a photodetection layer 320, an anti-reflective layer 330, and a color microlens layer 340 serving as a color filter are sequentially stacked.

Referring to FIG. 3, in the CMOS image sensor 300 including a color microlens according to another embodiment of the present invention, a color filter and a microlens are integrally formed with each other.

In this case, the heights of the color filter and the microlens for each color may differ according to a sequence in which a color process is performed. Furthermore, formation processes of the color filter and the microlens are simultaneously performed, so that processes of planarization, step difference adjustment and the like can be omitted.

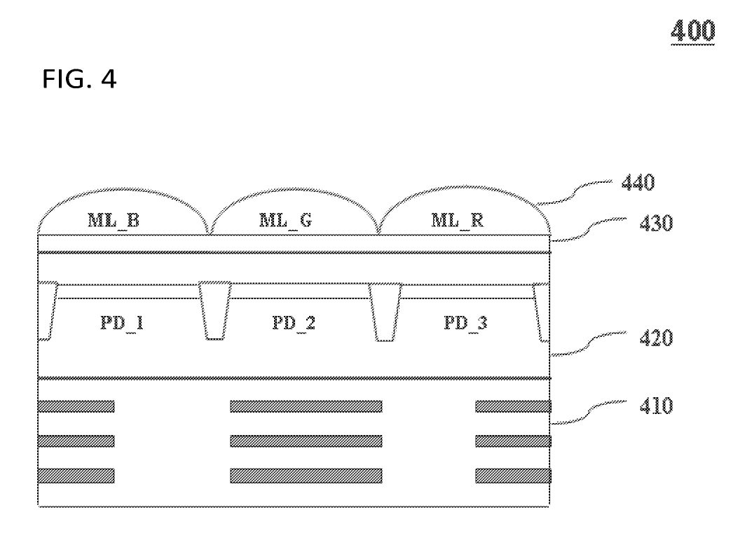

FIG. 4 is a diagram schematically illustrating a CMOS image sensor including a color microlens according to further another embodiment of the present invention.

As illustrated in FIG. 4, a CMOS image sensor 400 including a color microlens according to the present invention has a structure in which a metal interconnection layer 410, a photodetection layer 420, an anti-reflective layer 430, and a color microlens layer 440 are sequentially stacked.

Referring to FIG. 4, the CMOS image sensor 400 including a color microlens according to further another embodiment of the present invention includes only the microlens layer without a color filter, wherein the microlens layer is formed as a color microlens.

In this case, a focal distance of the color microlens may be appropriately adjusted in consideration of the structure in which there is no color filter.

In FIG. 2, FIG. 3 and FIG. 4, examples in which the color filter array (CFA) and the microlens include three colors of red, green, and blue have been described. However, the color filter array (CFA) and the microlens may include three colors of yellow, magenta, and cyan, or a black or white color.

Furthermore, each of the color filter array (CFA) and the microlens may be differently combined, so that colors in a final sensor may be differently specified. That is, the blue of the color filter array (CFA) and the red of the microlens may be combined to each other to achieve the magenta, the green of the color filter array (CFA) and the blue of the microlens may be combined to each other to achieve the cyan, or the red of the color filter array (CFA) and the green of the microlens may be combined to each other to achieve the yellow.

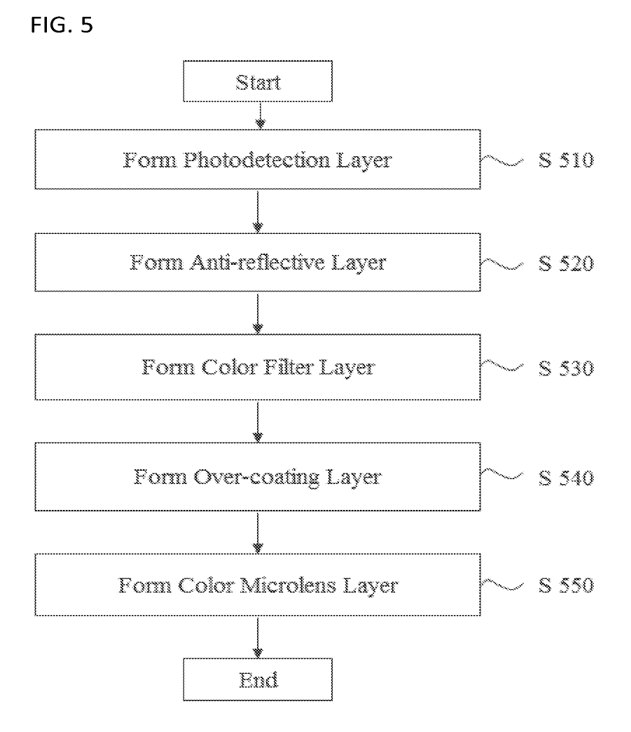

FIG. 5 is a flowchart illustrating a procedure of a manufacturing method of the CMOS image sensor including a color microlens of FIG. 2.

As illustrated in FIG. 5, the manufacturing method of the CMOS image sensor including a color microlens according to the present invention includes a step (S510) of forming a photodetection layer, a step (S520) of forming an anti-reflective layer, a step (S530) of forming a color filter layer, a step (S540) of forming an over-coating layer, and a step (S550) of forming a color microlens layer.

In the step (S510) of forming the photodetection layer, the photodetection layer including at least one photodiode for receiving light of at least one color is formed on a semiconductor substrate.

Next, in the step (S520) of forming the anti-reflective layer, the anti-reflective layer is formed on the photodetection layer.

In the step (S530) of forming the color filter layer, the color filter layer including at least one color filter is formed at positions, which respectively correspond to the at least one photodiode, over the anti-reflective layer.

Then, in the step (S540) of forming the over-coating layer, the over-coating layer including at least one over-coating formed at positions respectively corresponding to the at least one color filter is formed on the color filter layer.

Last, in the step (S550) of forming the color microlens layer, the color microlens layer including at least one color microlens formed at positions respectively corresponding to the at least one color filter is formed on the over-coating layer.

Conventionally, all microlenses have been formed at one time. However, in the present invention, since the formation process of the color microlens layer is performed for each color, CRA and Shift Equation for a lens can be differently optimized for each color, so that it is possible to improve optical properties.

Furthermore, in the conventional case, if light having passed through a microlens layer does not match with CRA, crosstalk occurs. However, in the case of the present invention, even though light having passed through a color microlens layer does not match with CRA, additional filtering can be performed in a lower color filter, so that it is possible to improve crosstalk characteristics.

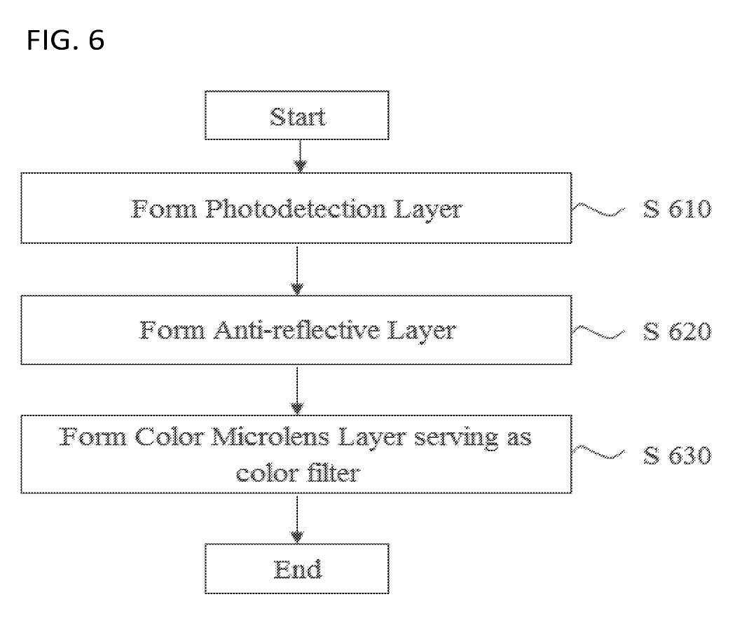

FIG. 6 is a flowchart illustrating a procedure of a manufacturing method of the CMOS image sensor including a color microlens of FIG. 3.

As illustrated in FIG. 6, the manufacturing method of the CMOS image sensor including a color microlens according to the present invention includes a step (S610) of forming a photodetection layer, a step (S620) of forming an anti-reflective layer, and a step (S630) of forming a color microlens layer serving as a color filter.

The step (S610) of forming the photodetection layer and the step (S620) of forming the anti-reflective layer are equal to those described in FIG. 5.

In the step (S630) of forming the color microlens layer serving as a color filter, the color microlens layer serving as a color filter and including a color microlens serving as at least one color filter formed at positions respectively corresponding to the at least one photodiode is formed on the anti-reflective layer.

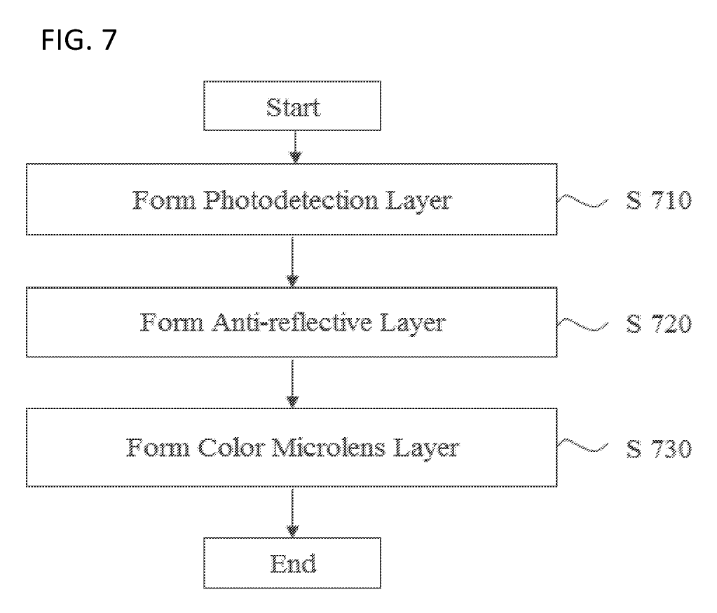

FIG. 7 is a flowchart illustrating a procedure of a manufacturing method of the CMOS image sensor including a color microlens of FIG. 4.

As illustrated in FIG. 7, the manufacturing method of the CMOS image sensor including a color microlens according to the present invention includes a step (S710) of forming a photodetection layer, a step (S720) of forming an anti-reflective layer, and a step (S730) of forming a color microlens layer.

The step (S710) of forming the photodetection layer and the step (S720) of forming the anti-reflective layer are equal to those described in FIG. 5.

In the step (S730) of forming the color microlens layer, the color microlens layer including at least one color microlens formed at positions respectively corresponding to the at least one photodiode is formed on the anti-reflective layer.

As illustrated in FIG. 6 and FIG. 7, when a process of forming the over-coating layer is omitted and the processes of forming the color filter and the microlens are integrated with each other, since a procedure is simplified and the entire heights of the color filter layer and the microlens layer are reduced, optical properties are improved and interfaces among the color filter layer, the over-coating layer, and the microlens layer disappear, so that it is possible to further increase light efficiency.

Although a preferred embodiment of the present invention has been described for illustrative purposes, those skilled in the art will appreciate that various modifications, additions and substitutions are possible, without departing from the scope and the spirit of the invention as disclosed in the accompanying claims.

1. A CMOS image sensor including a color microlens, comprising:
a photodetection layer formed over a semiconductor substrate and including at least one photodiode for receiving light of at least one color;
an anti-reflective layer formed over the photodetection layer;
a color filter layer formed over the anti-reflective layer and including at least one color filter formed at positions respectively corresponding to the at least one photodiode;
an over-coating layer formed over the color filter layer and including at least one over-coating formed at positions respectively corresponding to the at least one color filter; and
a color microlens layer formed over the over-coating layer and including at least one color microlens formed at positions respectively corresponding to the at least one color filter.

2. A CMOS image sensor including a color microlens, comprising:
a photodetection layer formed over a semiconductor substrate and including at least one photodiode for receiving light of at least one color;
an anti-reflective layer formed over the photodetection layer; and
a color microlens layer serving as a color filter formed over the anti-reflective layer and including a color microlens serving as at least one color filter formed at positions respectively corresponding to the at least one photodiode.

3. A CMOS image sensor including a color microlens, comprising:
a photodetection layer formed over a semiconductor substrate and including at least one photodiode for receiving light of at least one color;
an anti-reflective layer formed over the photodetection layer; and
a color microlens layer formed over the anti-reflective layer and including at least one color microlens formed at positions respectively corresponding to the at least one photodiode.

4. The CMOS image sensor including the color microlens of claim 1, wherein the at least one color includes blue, green, and red colors, respectively.

5. The CMOS image sensor including the color microlens of claim 1, wherein the at least one color includes cyan, magenta, and yellow, respectively.

6. The CMOS image sensor including the color microlens of claim 1, wherein a color of the at least one color filter and a color of the at least one color microlens corresponding to the color are equal to or different from each other.

7. A manufacturing method of a CMOS image sensor including a color microlens, comprising the steps of:
forming a photodetection layer including at least one photodiode for receiving light of at least one color over a semiconductor substrate;
forming an anti-reflective layer over the photodetection layer;
forming a color filter layer including at least one color filter at positions respectively corresponding to the at least one photodiode over the anti-reflective layer;
forming an over-coating layer including at least one over-coating formed at positions respectively corresponding to the at least one color filter over the color filter layer; and
forming a color microlens layer including at least one color microlens formed at positions respectively corresponding to the at least one color filter over the over-coating layer.

8. A manufacturing method of a CMOS image sensor including a color microlens, comprising the steps of:
forming a photodetection layer including at least one photodiode for receiving light of at least one color over a semiconductor substrate;
forming an anti-reflective layer over the photodetection layer; and
forming a color microlens layer serving as a color filter and including a color microlens serving as at least one color filter formed at positions respectively corresponding to the at least one photodiode over the anti-reflective layer.

9. A manufacturing method of a CMOS image sensor including a color microlens, comprising the steps of:
forming a photodetection layer including at least one photodiode for receiving light of at least one color over a semiconductor substrate;
forming an anti-reflective layer over the photodetection layer; and
forming a color microlens layer including at least one color microlens formed at positions respectively corresponding to the at least one photodiode over the anti-reflective layer.

10. The manufacturing method of the CMOS image sensor including the color microlens of claim 7, wherein in the step of forming the color microlens layer, thicknesses of the at least one color microlens are formed to be equal to or different from each other.

11. The CMOS image sensor including the color microlens of claim 2, wherein the at least one color includes blue, green, and red colors, respectively.

12. The CMOS image sensor including the color microlens of claim 3, wherein the at least one color includes blue, green, and red colors, respectively.

13. The CMOS image sensor including the color microlens of claim 2, wherein the at least one color includes cyan, magenta, and yellow, respectively.

14. The CMOS image sensor including the color microlens of claim 3, wherein the at least one color includes cyan, magenta, and yellow, respectively.

15. The manufacturing method of the CMOS image sensor including the color microlens of claim 9, wherein in the step of forming the color microlens layer, thicknesses of the at least one color microlens are formed to be equal to or different from each other.
